(19) United States
(12) Patent Application Publication
(10) Pub. No.: US 2025/0293484 A1
(43) Pub. Date: Sep. 18, 2025

(54) CLADDING-LESS GAN-BASED THIN-FILM EDGE-EMITTING LASER

(71) Applicant: THE UNIVERSITY OF HONG KONG, Hong Kong (CN)

(72) Inventors: Hoi Wai CHOI, Hong Kong (CN); Wai Yuen FU, Hong Kong (CN)

(73) Assignee: THE UNIVERSITY OF HONG KONG, Hong Kong (CN)

(21) Appl. No.: 19/222,978

(22) Filed: May 29, 2025

Related U.S. Application Data
(63) Continuation-in-part of application No. PCT/CN2023/135141, filed on Nov. 29, 2023.
(60) Provisional application No. 63/428,993, filed on Nov. 30, 2022.

(51) Int. Cl. H01S 5/343; H01S 5/02; H01S 5/026; H01S 5/125

(52) U.S. Cl. CPC H01S 5/34333; H01S 5/0215; H01S 5/0217; H01S 5/026; H01S 5/125; H01S 5/0213

(57) ABSTRACT

A cladding-less GaN-based thin-film edge-emitting laser is formed by: attaching a typical LED wafer to a substrate; removing its sapphire substrate to expose its n-GaN and the u-GaN buffer layers; thinning the film thickness to maximize the overlap factor; depositing another reflective metallic layer on the n-GaN surface for optical confinement and electrical contact; defining a pattern of the edge-emitting cavity by nanolithography techniques; and using an ICP etch to transfer the pattern to the thin film. In a second embodiment, the LED epitaxy structure is transformed into a laser diode by bonding it to a substrate with a Bragg reflector. After bonding and substrate removal, the bottom of the LED epitaxy is exposed for etching. In a third embodiment, a polariton edge-emitting laser is formed by utilizing Distributed Bragg Reflectors (DBRs) on both sides of the edge-emitting laser.

### CROSS-REFERENCE TO RELATED PATENT APPLICATIONS

This application is a Continuation-in-Part of International Patent Application No. PCT/CN2023/135141, filed Nov. 29, 2023, and claims the benefit of priority under 35 U.S.C. Section 119 (e) of U.S. Application No. 63/428,993, filed Nov. 30, 2022, all of which are incorporated herein by reference in their entireties. The International Application was published in English on Jun. 6, 2024, as International Publication No. WO 2024/114692 A1.

### FIELD OF THE INVENTION

The present invention relates to thin-film-edge-emitting lasers and, more particularly, to cladding-less GaN-based thin-film-edge-emitting lasers.

### BACKGROUND OF THE INVENTION

There is an ever-growing interest in photonic integrated circuits (PIC), in which multiple photonic devices are integrated monolithically or heterogeneously at the systems level. The reason for this interest relates to the speed of light versus the speed of electrons in electronic integrated circuits (ICs), especially at a time when the scaling of electronic ICs as predicted by Moore's law is approaching its physical limit. These photonic integrated systems offer a number of advantages including increased functionality, scalability, speed, efficiency, dimensional downscaling, improved stability, robustness, and reduced power consumption. All of these advantages are important for the development of novel optically integrated systems such as optical communications, optical sensing and optical computing. PICs have been demonstrated using various material systems including Si [1, 2], GaAs [3, 4], InP [5, 6], and GaN [7-9]. While each material has its own merit, GaN with In and Al alloys is a well-rounded material system that has a wide and direct bandgap, giving wide wavelength coverage ranging from the deep ultraviolet to the visible band.

Visible light-emitting laser diodes based on GaN have been used as the basis for optical storage (Blu-ray), laser display and visible light communication. Typical forms of such laser diodes include vertical cavity surface-emitting lasers (VCSEL), and edge-emitting lasers [10, 11]. With horizontal stimulated emission, the edge-emitting laser is an ideal light source for on-chip photonic communication or integrated circuits, which have attracted a growing interest due to their advantages over their electronic counterparts, including functionality, scalability, speed, efficiency, dimensional downscaling, improved stability, robustness, and reduced power consumption.

An edge-emitting laser is a type of laser that has mirrors (or equivalent) on both sides of a waveguide containing a gain medium (the active region for a semiconductor laser). The quality of the laser beam emission from the laser depends on (a) the optical confinement, i.e., how good the beam is confined inside the waveguide, and (b) the effective gain of the gain medium, which usually depends on the internal quantum efficiency of the active region and how much of the guided beam overlaps within the active region.

Typically, for a semiconductor edge-emitting laser, a pair of cladding layers have to be grown above and below the active region, e.g., the multiple quantum wells (MQWs), to confine the light waves close to the active region. Unfortunately, the insertion of the pair of cladding layers into the epitaxy structure is detrimental to the internal quantum efficiency (IQE), both in terms of the growth quality and the design of the MQWs. Thus, the growth of high quality laser epitaxy structures with cladding layers is usually complicated and costly and has a low yield.

Conventionally, an edge-emitting laser has to be fabricated on an expensive custom-grown wafer with epitaxial cladding layers inserted to improve optical confinement and overlap between the active region and the modal profile. Without the insertion of the cladding layers, lasing would be impossible within the normal operation range, thus limiting the possibilities to integrate multiple photonic components on a single platform for applications such as a photonic integrated circuit. The epitaxially-grown low refractive index layers are usually inserted above and below the InGaN/GaN MQWs and GaN waveguiding layers to promote optical confinement. Due to lattice-matching with the GaN epitaxy, the AlGaN material is generally chosen as the cladding material to maintain the high material quality of the GaN-based epitaxial structure, as illustrated in FIGS. 1A and 1B. Nevertheless, while the AlGaN material does have a lower refractive index than the GaN material, the small difference in refractive index, typically about 0.1-0.2 depending on the composition [13], limits the effectiveness of the wave-guiding effect. Moreover, the growth of the layers can cause various issues. The high growth temperatures of the AlGaN layers adversely affect the vulnerable InGaN/GaN MQWs. The tensile strain induced by the layers could potentially lead to cracking. The performance of the device is thus impacted by the lower electrical conductivity of the thick AlGaN layers [14, 15].

FIG. 5A shows a conventional thin-film semiconductor edge-emitting laser with cladding layers grown; FIG. 5B shows the corresponding as-grown LED epitaxy with its original substrate before a thin-film process. The illustration in FIG. 5B is shown upside-down for side-by-side comparison with the structure in FIG. 5A. Note that the dash line illustrates the guided light.

US Application Publication No. 2022/0231477 discloses a flip-chip optoelectronic device in which a semiconductor die is attached with the bond pad side down onto a substrate or carrier. In the process for this design the original substrate is not removed after the flip-chip. Thus, the film thickness cannot be optimized. U.S. Pat. No. 10,554,017 discloses a method and device concerning a III-nitride edge emitting laser diode of high confinement factor with a lattice matched cladding layer. The laser structure is fabricated on a wafer grown with epitaxial AlGaN cladding layers. No lift-off processes are involved.

### SUMMARY OF THE INVENTION

One embodiment of a solution to the problems of constructing an edge emitting laser diode is to build the edge-emitting laser structure through external cladding layers by means of a thin film strategy. A typical light-emitting epitaxial structure can be bonded to a silicon substrate with a reflective metallic bonding, followed by the removal of its original substrate. The thickness of the epitaxial layer can thus be tailored via etching, before the deposition of an external metallic cladding layer for optical confinement.

This embodiment of present invention is directed to a method of fabricating an edge-emitting laser cavity structure that is free of cladding. By fabricating a conventional edge-emitting laser cavity structure on a thin film platform, the film thickness can be tuned to maximize the laser performance. The thin film platform is formed by bonding a typical GaN-based LED wafer on a Si substrate with the original substrate removed. The exposed bottom buffer layers following substrate removal, which are grown to minimize the material defects, can thus be removed through etching while leaving the LED active region intact. The waveguide of the laser is formed without adding any cladding layer. Instead, the structure of the LED is trimmed so that it becomes a thin cavity. The top GaN-air interface is naturally a waveguiding structure, while the bottom GaN/metal or GaN/DBR (distributed Bragg reflector) is another waveguide. The thinness of the cavity makes the overlap of the cavity modes with the gain region (the MQWs) very high. The laser performance is thus much improved with the thinned film, with the lasing threshold lowered to a feasible value for normal operation.

Thus, this embodiment makes use of a thin film platform for the fabrication of the edge-emitting laser structure. The thin film platform is formed by attaching the LED film from a conventional, commercially available LED wafer to a Si substrate. Since the film thickness can be fine-tuned through etching after removal of the original substrate, the laser performance can be improved, and the lasing threshold is lowered such that normal operation is feasible.

While both the thin film platform and edge-emitting laser already exist, the use of the thin film platform for fabrication of edge-emitting lasers is novel. By employing a thin film platform for laser fabrication, which platform can be assembled from a commercially available LED wafer, the laser performance can be improved without resorting to expensive custom-grown wafers or epitaxial cladding.

As a second way to address the issue with the cladding layers of the prior art, a second embodiment of the present invention is directed to a cladding-less process approach. The fabrication process starts with a conventional LED epitaxy structure without any cladding layers that supports little waveguiding. The use of LED epitaxy structure provides the advantages of (a) high IQE due to mature LED growth process and (b) cheaper cost due to mass production and large market of LED epitaxy structures.

The thin film process of this second embodiment transforms the LED epitaxy structure into a laser diode with high optical confinement and gain overlap. The LED epitaxy structure is bonded to a substrate, usually Si, with reflective metal or a conductive distributed Bragg reflector. The layer acts as a reflective layer replacing the p-cladding layer for bottom optical confinement while providing contact for electrical injection. After bonding and substrate removal, the bottom of the LED epitaxy is exposed for etching. The thin film processing of this embodiment of the present invention involves the removal of the thick semiconductor layers below the active region of the LED epitaxy for enhanced optical confinement and gain overlap. This is achieved by etching the layers to an optimal thickness.

In a third embodiment, the thin-film edge-emitting laser technology of the present invention is used to enable polariton lasing. A polariton edge-emitting laser is formed by utilizing Distributed Bragg Reflectors (DBRs) on both sides of the edge-emitting laser along the longer edges. This design strategically enhances the spatial overlap between the optical mode and the active medium, creating an ideal environment for efficient polariton formation and lasing.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing and other objects and advantages of the present invention will become more apparent when considered in connection with the following detailed description and appended drawings in which like designations denote like elements in the various views, and wherein:

FIG. 1A is a cross-sectional TEM image showing the InGaN/GaN MQW sandwiched between a pair of AlGaN cladding layers in a laser diode structure and FIG. 1B is an enlarged view of the active region shown in the box in FIG. 1A;

FIG. 2A is 3D perspective schematic diagram of the thin-film edge-emitting laser of a first embodiment of present invention, FIG. 2B is the corresponding layer structure of the thin-film edge-emitting laser of the present invention with a reflective metallic layer at the bottom and FIG. 2C shows a simulated electric field profile of the fundamental resonant mode of the thin-film edge-emitting laser;

FIG. 3A is 3D perspective schematic diagram of the second embodiment of the thin-film edge-emitting laser of the present invention and FIG. 3B is the corresponding layer structure of the thin-film edge-emitting laser of the present invention with a Distributed Bragg Reflector (DBR) at the bottom;

FIG. 4A is a photoluminescence (PL) spectra of a fabricated thin-film edge-emitting laser according to an embodiment of the present invention and FIG. 4B is a graph of the corresponding linewidth and integrated PL intensity with increasing excitation energy density of a fabricated thin-film edge-emitting laser according to an embodiment of the present invention;

FIG. 5A shows an illustration of a conventional thin-film semiconductor edge-emitting laser with cladding layers grown and FIG. 5B shows an upside down illustration of the corresponding as-grown LED epitaxy structure with its original substrate before a thin-film process;

FIG. 6A shows the second embodiment of the present invention in which the LED epitaxy structure is bonded to a Si substrate with reflective metal or conductive DBR, FIG. 6B shows an upside down illustration of an as-grown LED epitaxy before the thin-film process of the second embodiment of the present invention and FIG. 6C is a perspective illustration of the second embodiment of the present invention.

FIG. 7A shows the electroluminescence (EL) spectra of the cladding-less edge-emitting laser of the second embodiment of the present invention and FIG. 7B shows the full-width half-maximum (FWHM) and intensity of the lasing peak plotted with respect to the current density;

FIG. 8 is a cross-sectional SEM image of a DBR structure of the present invention;

FIG. 9 is a graph of reflectivity spectra simulated and measured from DBR samples of the present invention;

FIG. 10A shows the experimentally obtained near-field emission profile of a resonant mode analysis of InGaN-based edge-emitting lasers on a thin-film platform revealing the spatial mode distribution of the edge-emitting laser and FIG. 10B is a simulated electric field intensity distribution derived from finite-element simulations;

FIG. 11A is a graph of the calculated polariton dispersion of an InGaN-based polariton edge-emitting laser (EEL) on a thin-film platform, FIG. 11B is an SEM image of the fabricated polariton edge-emitting laser, revealing the optimized device structure engineered for achieving polariton lasing with PL intensity and full width at half maximum (FWHM) as a function of excitation power density under polariton lasing in FIG. 11C and under photon lasing in FIG. 11D; and

FIG. 12A an SEM image showing the monolithic integration of a photodetector with an InGaN-based edge-emitting laser (EEL) and FIG. 12B shows the SEM image for a polariton EEL on the thin-film platform.

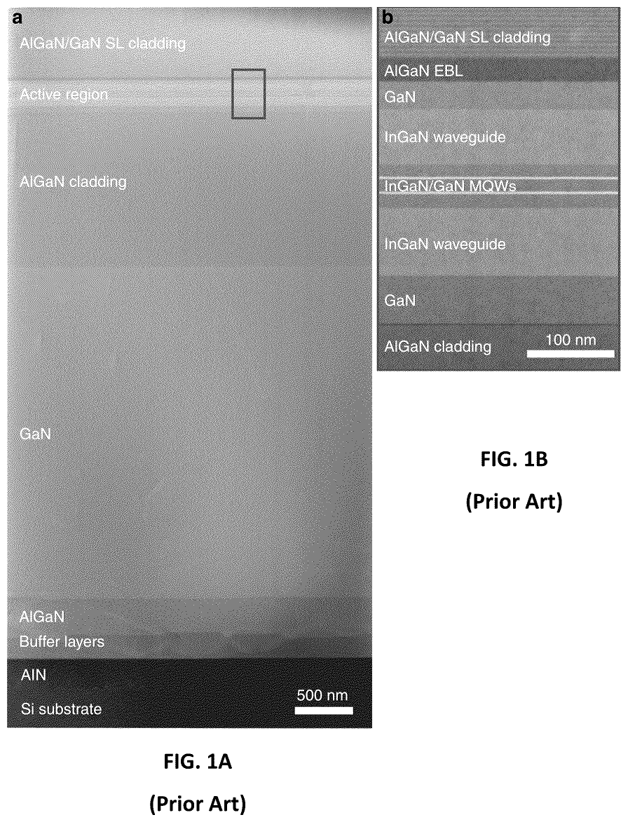

### DETAILED DESCRIPTION OF THE INVENTION

The design of thin-film edge-emitting lasers according to an embodiment of the present invention eliminates the need to grow cladding layers within the epitaxial structure, relying instead on external reflectors for optical confinement. Such reflectors, including metallic mirrors, also function as electrical contacts or dielectric distributed Bragg reflectors (DBR) and provide superior optical confinement to further enhance modal gain.

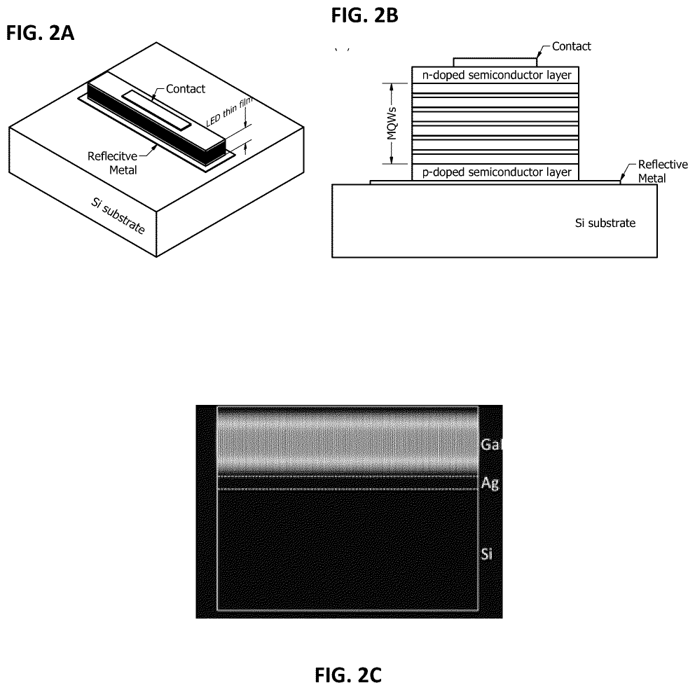

A 3D perspective view and the corresponding layer structure of a platform for creating the edge-emitting laser of a first embodiment of the present invention is shown in FIGS. 2A & 2B, respectively. The first step in attaining the laser structure of this embodiment of the present invention is to attach a typical LED wafer to a Si substrate through eutectic bonding. Gold (Ag) is preferred as a metallic bonding material because of its high reflectivity. An original sapphire substrate of the LED wafer is then removed by a laser lift-off process, thus exposing the n-GaN and the u-GaN buffer layers. An inductively coupled plasma (ICP) etch can then be employed to thin the film thickness to maximize the overlap factor between the resonant mode profile and the active region, i.e., the multiple quantum wells (MQWs). In fact, the flexibility to fine-tune the cavity thickness for overlap factor optimization is the major advantage of this thin-film approach. A reflective metallic layer is then deposited on the n-GaN surface for optical confinement and electrical contact. Finally, the pattern of the edge-emitting cavity can then be defined by nanolithography techniques such as direct laser writing lithography, electron beam lithography or nanoimprint lithography, followed by an ICP etch to transfer the pattern to the thin film.

Two dimensional Finite-Difference Time-Domain (FDTD) simulations were performed to analyze the resonant mode of the edge-emitting laser cavity. The simulated electric field profile of the fundamental resonant mode is shown in FIG. 2C, demonstrating a high Q factor of 26,000 with a confinement factor of 0.71. To verify the feasibility of the design, an edge-emitting laser with a Fabry-Pérot cavity was fabricated on a thin film MQW sample with an emission wavelength of 444 nm. An LED on a sapphire sample was first wafer-bonded to a Si substrate, and the sapphire substrate was subsequently removed by laser lift off (LLO) etching. An inductively coupled plasma (ICP) etch was undertaken to thin the sample to a thickness of around 500 nm. A laser direct writer was then used to pattern a rectangular block followed by an ICP etch to form an edge-emitting laser. Preliminary experimental data was obtained by optical-pumping the fabricated edge-emitting laser with a diode-pumped solid-state (DPSS) laser emitting at 349 nm with a pulse width of 4 ns and a repetition rate of 1 kHz. As shown in FIGS. 4A &4B, lasing is observed at a threshold of 1.1 mJ/cm² with a Q factor of ˜1100 at the wavelength of ˜444 nm.

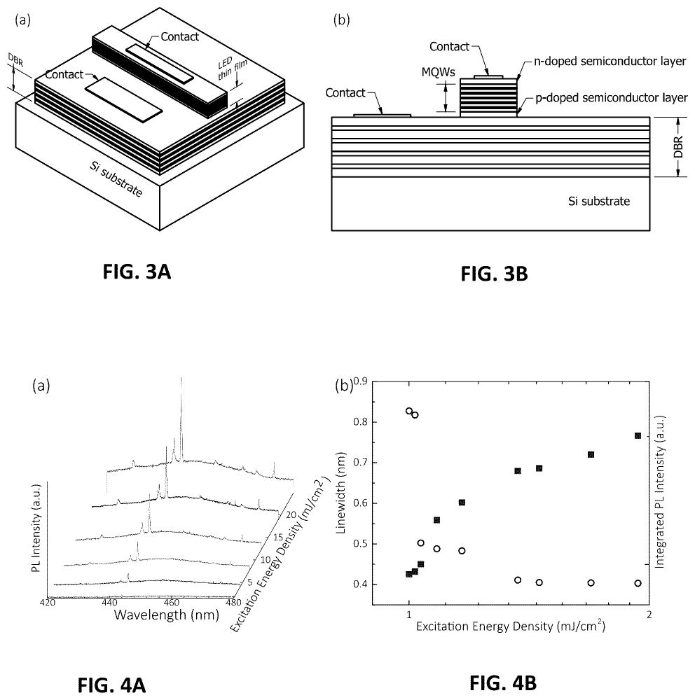

The simulation and experimental studies verified the feasibility of the thin-film edge-emitting laser design. The fabrication of such a device is relatively simple and can easily be adapted to different applications for potential commercialization. The performance of the design can be improved by replacing the reflective metallic layers with pairs of distributed Bragg reflectors (DBRs), as illustrated in FIGS. 3A & 3B.

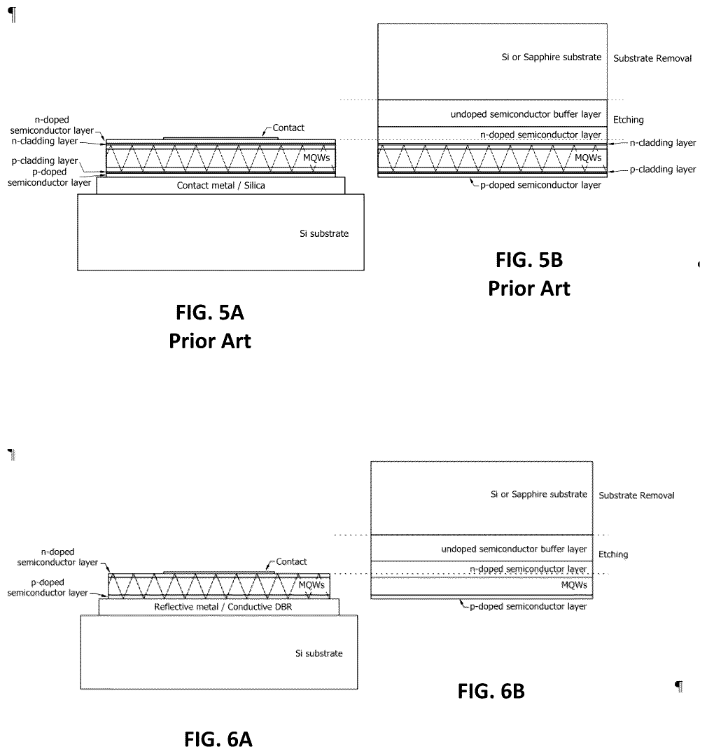

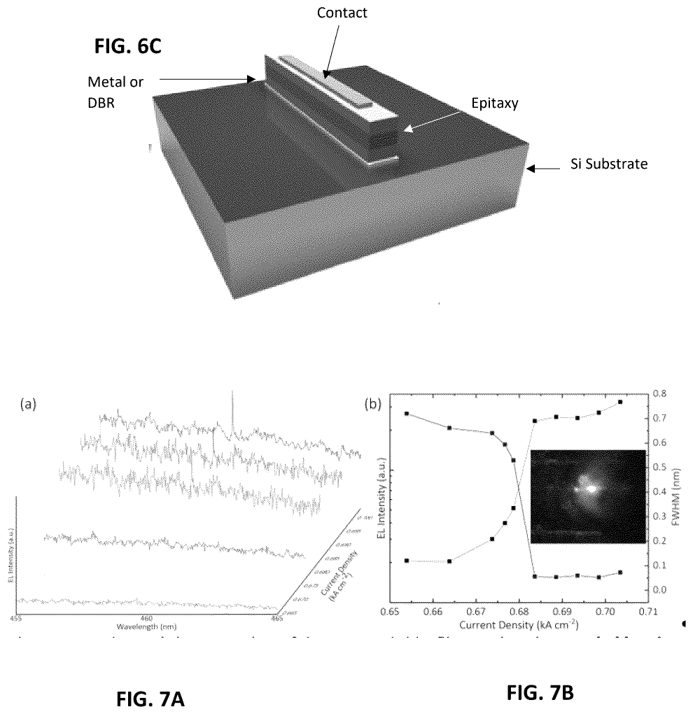

As a second way to address the issue of the cladding layers in the epitaxial structure, a second embodiment of the present invention is directed to a cladding-less process approach. The fabrication process starts with conventional LED epitaxy without any cladding layers that supports little waveguiding. See FIG. 6A. Any guided waves would spread all over the thick LED epitaxy structure, and thus there is little overlap with the active region, and it will not induce population inversion for laser beam generation. In contrast, conventional laser epitaxy structure with cladding layers supporting laser beam generation even without the thin film process, as shown in FIG. 5A. The use of LED epitaxy structure provides the advantages of (a) high IQE due to a mature LED growth process and (b) cheaper cost due to mass production and large market of LED epitaxy.

The thin film process of this second embodiment transforms the LED epitaxy structure into a laser diode with high optical confinement and gain overlap. As shown in FIG. 6A, the LED epitaxy structure is bonded to a Si substrate with reflective metal or conductive DBR. The layer acts as a reflective layer replacing the p-cladding layer illustrated in FIG. 5A for bottom optical confinement, while providing a contact for electrical injection. After bonding the Si substrate is removed. Then the bottom of the LED epitaxy is exposed for etching. Note that even in conventional laser epitaxy, the thick semiconductor layers below the cladding layers are useless for optical confinement; however, they are crucial during the growth to mitigate defects such as dislocations and stacking faults, i.e., to enhance the film quality. As such, the proposed thin film process of the second embodiment allows for removal of such layers from the LED epitaxy for enhancing optical confinement and gain overlap. This is achieved by etching to an optimal thickness.

For a typical edge-emitting laser or waveguide, the cavity thickness is usually N times the emission wavelength divided by the refractive index of the semiconductor material used. Given the limitation of the thickness of the p-doped semiconductor layer and MQWs that must not be removed, N is usually chosen to be the smallest number (for maximizing the overlap between guided light beam and the active region) such that the MQWs are close to the center of the epitaxy after etching. The actual number would depend on the thicknesses of the p-doped semiconductor layer and the initial MQWs of the LED epitaxy.

FIG. 6A shows the proposed thin-film semiconductor, cladding-less edge-emitting laser. FIG. 6B shows the as-grown LED epitaxy before the thin-film process but is illustrated upside-down for side-by-side comparison. Note that the dash line illustrates the guided light. FIG. 6C is a perspective view of the device.

Comparing the proposed thin-film semiconductor, cladding-less edge-emitting laser (FIGS. 6A & 6B)) with conventional thin-film semiconductor edge-emitting laser (FIGS. 5A & 5B), it is obvious that the design of the present invention is much better in optical confinement as compared to conventional laser epitaxy.

Due to the limitation of the growth of conventional laser epitaxy, the choices of cladding materials are very limited as it has to have a lattice parameter similar to that of the semiconductor material of the epitaxy to avoid deterioration of the film quality. Thus, the difference between the refractive index of the cladding material and the semiconductor material is very low, leading to a low reflectivity and thus low optical confinement.

On the other hand, the bottom reflective layer of the proposed design uses either a reflective metal (>90% reflectivity) or conductive DBR (>95%) reflectivity, which is much higher than that of typical cladding layers. For the top surface, the light is guided by the total internal reflection induced by the high refractive index contrast between the air and the semiconductor material (instead of semiconductor material and cladding material).

FIGS. 7A & 7B show the results of an experimental demonstration of the proposed thin-film semiconductor, cladding-less edge-emitting laser based on an InGaN/GaN LED epitaxy according to the present invention. FIG. 7A shows the EL spectra and FIG. 7B shows the full-width half-maximum (FWHM) and intensity of the lasing peak plotted with respect to the current density.

An updated prototype of the proposed design has been fabricated using a blue-emitting InGaN/GaN LED wafer. The experimental results are shown in the insert of FIG. 7B, demonstrating the capability of the laser generation of the design under electrical injection.

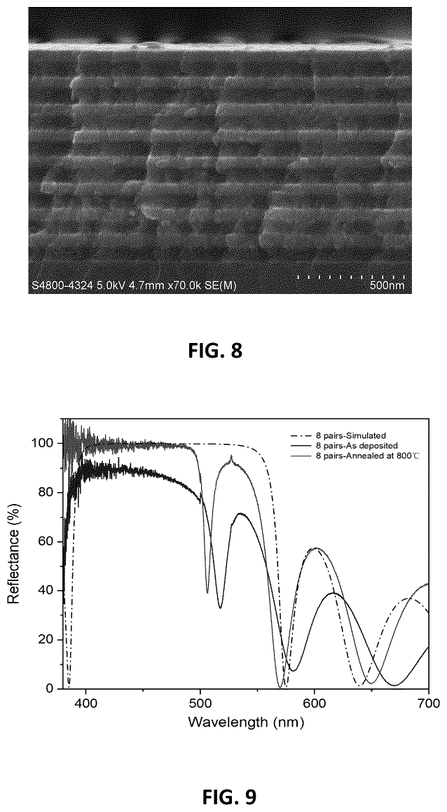

For a demonstration of the effect of the implementation of DBR in the thin film approach, 8 pairs of SiO2/TiO2 dielectric DBR were deposited on a p-GaN surface of the GaN LED wafer located on the Si substrate. The structure was then annealed. The SiO2/TiO2 DBR structure exhibited a reflectivity >99% at the emission wavelengths of the LED epitaxy. FIG. 8 is an SEM image of the TiO2/SiO2 dielectric DBR structure and FIG. 9 is a graph of the reflectivity spectra simulated and measured from DBR samples.

Thus, a combination of the thin film structure and highly reflective DBR contribute to high overlap factors and strong optical confinement, significantly improving the Q factor of the GaN-based edge-emitting laser and reducing the laser threshold. Thus, the design of the present invention has great potential for realizing a high-performance cladding-less edge-emitting laser using a conductive DBR.

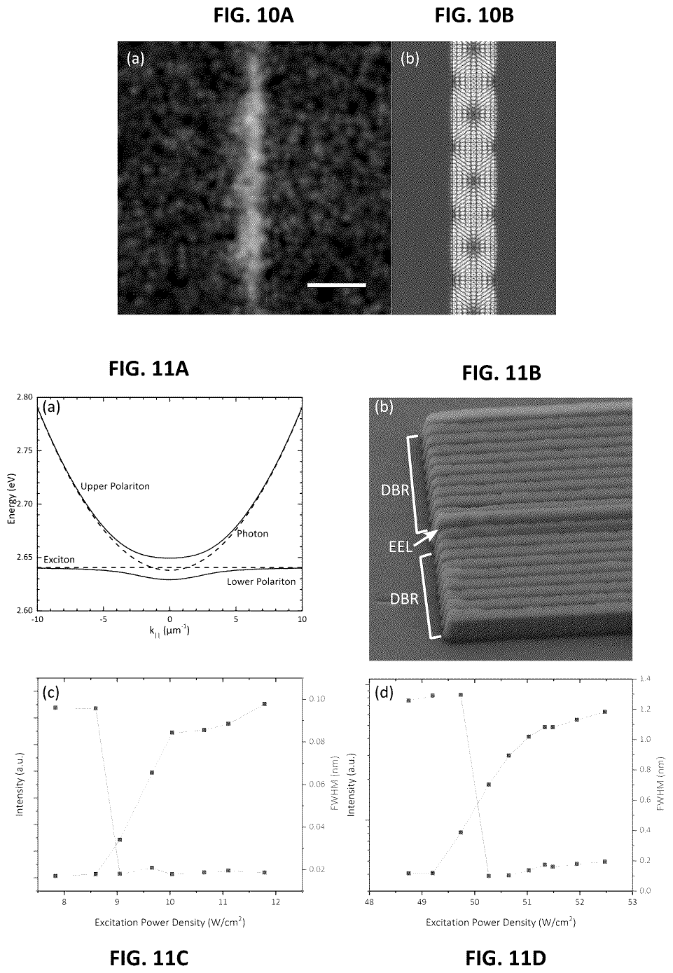

To elucidate the spatial mode distribution and optical confinement properties of the InGaN-based edge-emitting lasers on the thin-film platform, a comprehensive SNOM photoluminescence (PL) study was conducted. During the study the devices were excited by a 405 nm continuous-wave laser incident in the far-field, while the resultant emission was collected through a fiber probe positioned in close proximity to the laser cavity surface. The experimentally obtained near-field emission profiles (FIG. 10A) exhibit a remarkable agreement with the simulated electric field intensity distributions derived from finite-element simulations (FIG. 10B). This concordance unequivocally confirms the designed resonant mode patterns and waveguiding mechanisms, validating the optical confinement achieved in these edge-emitting laser configurations. However, it should be noted that the measured/simulated emission profiles as shown in FIGS. 10A and 10B are very specific to the dimension fabricated/simulated, and will change if the dimension, especially the width, changes.

Building upon the remarkable success of the thin-film edge-emitting laser technology, further strides have been made in advancing the design to enable polariton lasing. The polariton dispersion is first calculated to identify the optimal device parameters and optical confinement conditions that foster strong light-matter coupling and the formation of polariton states (FIG. 11A). The resulting dispersion curve exhibits the characteristic anti-crossing behavior, a hallmark of the strong coupling regime essential for achieving polariton lasing.

Guided by these theoretical insights, a third embodiment of the present invention is a device structure and fabrication process designed for a polariton edge-emitting laser, as shown in the SEM image in FIG. 11B. Utilizing Distributed Bragg Reflectors (DBRs) on both sides of the edge-emitting laser along the longer edges, the design strategically enhances the spatial overlap between the optical mode and the active medium, creating an ideal environment for efficient polariton formation and lasing.

To experimentally validate the successful realization of polariton lasing, extensive PL studies were conducted on the fabricated devices. The PL measurements unequivocally demonstrate the achievement of both polariton lasing and photon lasing within the same device, as shown in FIG. 11C and FIG. 11D, respectively. The polariton lasing threshold is significantly lower than that of photon lasing, a distinctive feature of polariton-based coherent emission.

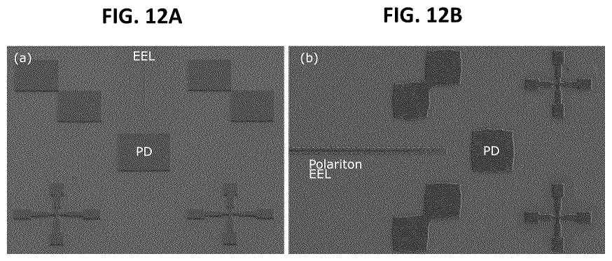

To explore the potential of the thin-film InGaN edge-emitting laser technology for on-chip photonic integrated circuits, a sample was fabricated by incorporating a photodetector at the end of the edge-emitting laser cavity. This integration allowed for an initial assessment of the device's performance in a practical photonic circuit setting. FIG. 12A and FIG. 12B present SEM images of the fabricated devices, showcasing the seamless integration of the photodetector with an edge-emitting laser or polariton edge-emitting laser. This lays the foundation for further investigations into the applicability and optimization of this technology for advanced photonic integrated circuits.

### REFERENCES

The cited references in this application are incorporated herein by reference in their entirety and are as follows:
[1] T. Komljenovic, M. Davenport, J. Hulme, A. Y. Liu, C. T. Santis, A. Spott, S. Srinivasan, E. J. Stanton, C. Zhang, and J. E. Bowers, “Heterogeneous silicon photonic integrated circuits,” Journal of Lightwave Technology, vol. 34, pp. 20, 2016.
[2] A. Liu, L. Liao, Y. Chetrit, J. Basak, H. Nguyen, D. Rubin, and M. Paniccia, “Wavelength division multiplexing based photonic integrated circuits on silicon-on-insulator platform,” IEEE Journal of Selected Topics in Quantum Electronics, vol. 16, pp. 23, 2010.
[3] J. J. Coleman, R. M. Lammert, M. L. Osowski, and A. M. Jones, “Progress in InGaAs—GaAs selective-area MOCVD toward photonic integrated circuits,” IEEE Journal of Selected Topics in Quantum Electronics, vol. 3, pp. 874, 1997.
[4] C. P. Dietrich, A. Fiore, M. G. Thompson, M. Kamp, and S. Höfling, “GaAs integrated quantum photonics: Towards compact and multi-functional quantum photonic integrated circuits,” Laser & Photonics Reviews, vol. 10, pp. 870, 2016.
[5] R. Nagarajan, M. Kato, J. Pleumeekers, P. Evans, S. Corzine, S. Hurtt, A. Dentai, S. Murthy, M. Missey, R. Muthiah, R. A. Salvatore, C. Joyner, R. Schneider, M. Ziari, F. Kish, and D. Welch, “InP photonic integrated circuits,” IEEE Journal of Selected Topics in Quantum Electronics, vol. 16, pp. 1113, 2010.
[6] M. Smit, K. Williams, and J. v. d. Tol, “Past, present, and future of InP-based photonic integration,” APL Photonics, vol. 4, p. 050901, 2019.
[7] R. Hui, S. Taherion, Y. Wan, J. Li, S. X. Jin, J. Y. Lin, and H. X. Jiang, “GaN-based waveguide devices for long-wavelength optical communications,” Applied Physics Letters, vol. 82, pp. 1326, 2003.
[8] K. H. Li, Y. F. Cheung, W. Y. Fu, K. K. Y. Wong, and H. W. Choi, “Monolithic integration of GaN-on-sapphire light-emitting diodes, photodetectors, and waveguides,” IEEE Journal of Selected Topics in Quantum Electronics, vol. 24, p. article no. 3801706, 2018.
[9] K. H. Li, W. Y. Fu, Y. F. Cheung, K. K. Y. Wong, Y. Wang, K. M. Lau, and H. W. Choi, “Monolithically integrated InGaN/GaN light-emitting diodes, photodetectors, and waveguides on Si substrate,” Optica, vol. 5, p. 564, 2018.
[10] A. Liu, P. Wolf, J. A. Lott, and D. Bimberg, “Vertical-cavity surface-emitting lasers for data communication and sensing,” Photonics Research, vol. 7, pp. 121, 2019.
[11] K. H. Li, W. Y. Fu, and H. W. Choi, “Chip-scale GaN integration,” Progress in Quantum Electronics, vol. 70, p. article no. 100247, 2020.
[12] Y. Sun, K. Zhou, M. Feng, Z. Li, Y. Zhou, Q. Sun, J. Liu, L. Zhang, D. Li, X. Sun, D. Li, S. Zhang, M. Ikeda, and H. Yang, “Room-temperature continuous-wave electrically pumped InGaN/GaN quantum well blue laser diode directly grown on Si,” Light: Science & Applications, vol. 7, p. 13, 2018.
[13] U. Tisch, B. Meyler, O. Katz, E. Finkman, and J. Salzman, “Dependence of the refractive index of AlxGal-xN on temperature and composition at elevated temperatures,” Journal of Applied Physics, vol. 89, pp. 2676, 2001.
[14] C. Chua, Z. Yang, C. Knollenberg, M. Teepe, B. Cheng, A. Strittmatter, D. Bour, and N. Johnson, “InAlGaN optical emitters: Laser diodes with non-epitaxial cladding layers and ultraviolet light-emitting diodes,” vol. 7939: SPIE, 2011.
[15] D. F. Feezell, M. C. Schmidt, R. M. Farrell, K.-C. Kim, M. Saito, K. Fujito, D. A. Cohen, J. S. Speck, S. P. DenBaars, and S. Nakamura, “AlGaN-cladding-free nonpolar InGaN/GaN laser diodes,” Japanese Journal of Applied Physics, vol. 46, pp. L284, 2007.
   While the invention is explained in relation to certain embodiments, it is to be understood that various modifications thereof will become apparent to those skilled in the art upon reading the specification. Therefore, it is to be understood that the invention disclosed herein is intended to cover such modifications.

1. A method for fabricating a cladding-less GaN-based thin-film edge-emitting laser comprising the steps of:
attaching a typical LED wafer to a Si substrate;
removing an original sapphire substrate of the LED wafer to expose its n-GaN and the u-GaN buffer layers;
thinning the film thickness to maximize the overlap factor between the resonant mode profile and the active region;
defining a pattern of the edge-emitting cavity by nanolithography techniques;
etching to transfer the pattern to the thin film by an ICP etch; and
depositing another reflective metallic layer on the n-GaN surface for optical confinement and electrical contact.

2. The method for fabricating a cladding-less GaN-based thin-film edge-emitting laser according to claim 1 wherein the step of attaching is achieved by eutectic bonding.

3. The method for fabricating a cladding-less GaN-based thin-film edge-emitting laser according to claim 2 wherein the metallic bonding material is Ag.

4. The method for fabricating a cladding-less GaN-based thin-film edge-emitting laser according to claim 1 wherein the step of removing the original sapphire substrate is achieved by a laser lift-off process.

5. The method for fabricating a cladding-less GaN-based thin-film edge-emitting laser according to claim 1 wherein the step of thinning the film thickness is achieved by inductively coupled plasma (ICP) etching.

6. The method for fabricating a cladding-less GaN-based thin-film edge-emitting laser according to claim 1 wherein the nanolithography techniques include one of direct laser writing lithography, electron beam lithography or nanoimprint lithography.

7. The method for fabricating a cladding-less GaN-based thin-film edge-emitting laser according to claim 1 wherein thinning the film thickness is performed to fine-tune the cavity thickness for overlap factor optimization.

8. A method for fabricating a cladding-less GaN-based thin-film edge-emitting laser comprising the steps of:
bonding a LED epitaxy structure to a Si substrate with one of a reflective metal and a conductive distributed Bragg reflector (DBR) for bottom optical confinement and for providing a contact for electrical injection;
removing the Si substrate after the step of bonding to expose the bottom of the LED epitaxy; and
etching the LED epitaxy to an optimal thickness for lasing.

9. A cladding-less GaN-based thin-film edge-emitting laser comprising:
a conductive distributed Bragg reflector (DBR) for bottom optical confinement and for providing a contact for electrical injection;
p and n-doped semiconductor layers forming an active region with the multiple quantum wells (MQWs) and
a contact layer on the top.

10. A cladding-less polariton laser comprising:
an edge-emitting laser; and
Distributed Bragg Reflectors (DBRs) on both sides of the edge-emitting laser along the longer edges arranged so as to enhance the spatial overlap between the optical mode and the active medium, creating an environment for efficient polariton formation and lasing.

11. An on-chip photonic integrated circuits comprising:
an edge-emitting laser cavity according to claim 10; and
a photodetector incorporated at the end of the edge-emitting laser cavity.
